(19) United States
(12) Patent Application Publication
(10) Pub. No.: US 2023/0206976 A1
(43) Pub. Date: Jun. 29, 2023

(54) SEMICONDUCTOR DEVICE

(71) Applicant: SAMSUNG ELECTRONICS CO., LTD., Suwon-si (KR)

(72) Inventors: Kyunghwan LEE, Seoul (KR); Yongseok KIM, Suwon-si (KR); Hyuncheol KIM, Seoul (KR); Jongman PARK, Hwaseong-si (KR); Dongsoo WOO, Seoul (KR); Minjun LEE, Seoul (KR)

(21) Appl. No.: 17/875,730

(22) Filed: Jul. 28, 2022

(30) Foreign Application Priority Data
Dec. 24, 2021 (KR) 10-2021-0187747

(51) Int. Cl. G11C 11/22; H01L 27/11597; H01L 21/28

(52) U.S. Cl. CPC G11C 11/223; G11C 11/2255; G11C 11/2257; H01L 27/11597; H01L 29/40111

(57) ABSTRACT

A semiconductor device including a substrate; a stack including electrodes and a channel separation pattern, the electrodes being stacked on the substrate and spaced apart from each other, and the channel separation pattern being between adjacent electrodes; and a vertical structure penetrating the stack, wherein the vertical structure includes a conductive pillar, a channel structure, and an interposing layer between the conductive pillar and the channel structure, the channel structure includes first and second channel layers vertically spaced apart from each other by the channel separation pattern, the electrodes include first and second electrodes, which are connected to the first and second channel layers, the channel separation pattern is between the first channel layer and the second channel layer, and the channel separation pattern is between one second electrode that is connected to the first channel layer and one first electrode that is connected to the second channel layer.

### CROSS-REFERENCE TO RELATED APPLICATION

This U.S. non-provisional patent application claims priority under 35 U.S.C. § 119 to Korean Patent Application No. 10-2021-0187747, filed on Dec. 24, 2021, in the Korean Intellectual Property Office, the entire contents of which are hereby incorporated by reference.

### BACKGROUND

### 1. Field

Embodiments relate to a semiconductor device.

### 2. Description of the Related Art

Semiconductor memory devices may include volatile memory devices and nonvolatile memory devices. The volatile memory devices lose their stored data when their power supplies are interrupted, and may include, e.g., a dynamic random access memory (DRAM) device or a static random access memory (SRAM) device. The nonvolatile memory devices maintain their stored data even when their power supplies are interrupted and may include, e.g., a programmable read only memory (PROM), an erasable PROM (EPROM), an electrically EPROM (EEPROM), or a flash memory device.

### SUMMARY

The embodiments may be realized by providing a semiconductor device including a substrate; a stack including electrodes and a channel separation pattern, the electrodes being stacked on the substrate and spaced apart from each other, and the channel separation pattern being between some adjacent ones of the electrodes; and a vertical structure penetrating the stack, wherein the vertical structure includes a conductive pillar, a channel structure, and an interposing layer between the conductive pillar and the channel structure, the channel structure includes a first channel layer and a second channel layer, which are vertically spaced apart from each other by the channel separation pattern, the electrodes include first electrodes and second electrodes, which are connected to one of the first channel layer and the second channel layer, the channel separation pattern is between the first channel layer and the second channel layer, and the channel separation pattern is between one second electrode that is connected to the first channel layer and one first electrode that is connected to the second channel layer.

The embodiments may be realized by providing a semiconductor device including a substrate; a lower insulating layer on the substrate; a stack including electrodes stacked on the lower insulating layer and spaced apart from each other; and a vertical structure penetrating the stack, wherein the vertical structure includes a conductive pillar, a channel structure, and an interposing layer between the conductive pillar and the channel structure, the channel structure is an outermost part of the vertical structure and is connected to the electrodes, and a bottom surface of the channel structure is at a level between a top surface and a bottom surface of the lower insulating layer.

The embodiments may be realized by providing a semiconductor device including a substrate; stacks on the substrate, the stacks being spaced apart from each other in a first direction; and a vertical structure penetrating each of the stacks, wherein each of the stacks includes a first electrode and a second electrode, which is stacked on the first electrode, the first electrode and the second electrode each extend in a second direction to be parallel to each other, and the vertical structure includes a conductive pillar extending in a third direction perpendicular to the first direction and the second direction; a channel layer connecting the first electrode and the second electrode to each other; and a ferroelectric layer between the conductive pillar and the channel layer.

### BRIEF DESCRIPTION OF THE DRAWINGS

Features will be apparent to those of skill in the art by describing in detail exemplary embodiments with reference to the attached drawings in which:

FIG. 1 is a circuit diagram of a semiconductor device according to an embodiment.

FIG. 2 is a plan view of a semiconductor device according to an embodiment.

FIG. 3 is a sectional view taken along a line I-I′ of FIG. 2.

FIGS. 4A and 4B are sectional views of portions ‘A’ and ‘B’, respectively, of FIG. 3.

FIGS. 5A and 5B are enlarged sectional views, of a portion (e.g., ‘B’ of FIG. 3) of a semiconductor device according to an embodiment.

FIG. 6 is an enlarged sectional view of a portion (e.g., ‘A’ of FIG. 3) of a semiconductor device according to an embodiment.

FIGS. 7A and 7B are sectional views, each of which is taken along a line I-I′ of FIG. 2 of a semiconductor device according to an embodiment.

FIGS. 8A and 8B are enlarged sectional views, of a portion (e.g., ‘A’ of FIG. 3) of a semiconductor device according to an embodiment.

FIG. 9 is a circuit diagram of a semiconductor device according to an embodiment.

FIG. 10 is a sectional view of a semiconductor device according to an embodiment.

FIG. 11 is an enlarged sectional view of a portion ‘C’ of FIG. 10.

FIGS. 12A to 12J are sectional views, which are taken along the line I-I′ of FIG. 2, of stages in a method of fabricating a semiconductor device according to an embodiment.

FIG. 13 is a perspective view of a semiconductor device according to an embodiment.

FIGS. 14, 15, and 16 are sectional views of a semiconductor device according to an embodiment.

### DETAILED DESCRIPTION

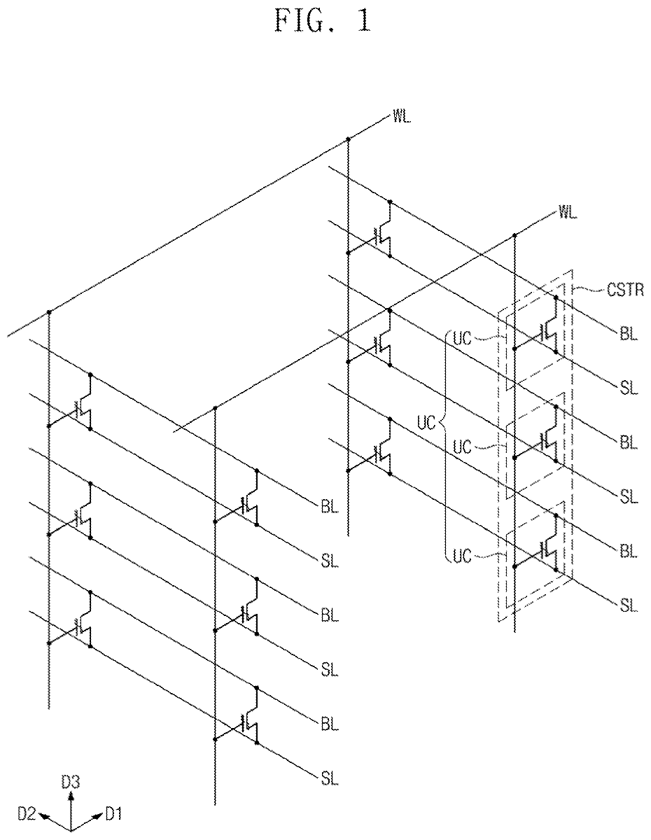

FIG. 1 is a circuit diagram of a semiconductor device according to an embodiment.

Referring to FIG. 1, a semiconductor device according to an embodiment may include word lines WL, bit lines BL, source lines SL, and cell strings CSTR. The cell strings CSTR may include unit cells UC, which are connected in common to the word lines WL. Each of the unit cells UC may be a unit memory cell of a ferroelectric random access memory (FeRAM) device.

The word lines WL may be extended in a first direction D1 to be parallel to each other. The word lines WL may be spaced apart from each other in a second direction D2. Each of the word lines WL may be connected to the cell strings CSTR arranged in the first direction D1. Each of the word lines WL may be electrically connected to gate terminals of the unit cells UC, which are arranged in a third direction D3 (i.e., vertically stacked).

The bit lines BL and the source lines SL may extend (e.g., lengthwise) in the second direction D2 to be parallel to each other. The bit lines BL and the source lines SL may be alternately arranged in the third direction D3. The bit lines BL may be electrically connected to drain terminals of the unit cells UC. The source lines SL may be electrically connected to source terminals of the unit cells UC. Each of the bit lines BL may be electrically connected to the drain terminals of the unit cells UC arranged in the second direction D2. Each of the source lines SL may be electrically connected to the source terminals of the unit cells UC arranged in the second direction D2.

The cell strings CSTR, which are arranged in the first direction D1, may be connected in common to one of the word lines WL. In an implementation, gate terminals of the unit cells UC in the cell strings CSTR arranged in the first direction D1 may be connected in common to a single word line WL extending in the first direction D1.

Each of the unit cells UC may be between the bit line BL and the source line SL, which are adjacent to each other in the third direction D3. The unit cells UC, which are arranged in the second direction D2, may be between the bit line BL and the source line SL which are adjacent to each other. In an implementation, the unit cells UC, which are at the same height or level and are arranged in the second direction D2, may be connected to in common to one of the bit lines BL and one of the source lines SL.

Each of the unit cells UC may include a ferroelectric material having a variable polarization state, and the polarization state of the ferroelectric material may be used to represent data stored in each of the unit cells UC. Each of the unit cells UC may be configured to allow the ferroelectric material to have one of two or more polarization states or to output an electric signal corresponding to each polarization state. In an implementation, each of the unit cells UC may be configured to allow the ferroelectric material to store or output a logical data of ‘1’ or ‘0’.

The ferroelectric material may be polarized by control signals applied to the word line WL, the bit line BL, and the source line SL. In an implementation, the word line WL, the bit line BL, and the source line SL may be configured to apply a voltage to the ferroelectric material, and in this case, a polarization state of the ferroelectric material may be changed depending on a direction of an electric field applied to the ferroelectric material. The data stored in the unit cell UC may be read out by comparing a current, which is output through the bit line BL, with a reference current. The polarization of the ferroelectric material may be preserved even when an electric power is interrupted. In an implementation, the semiconductor device according to an embodiment may be a nonvolatile memory device.

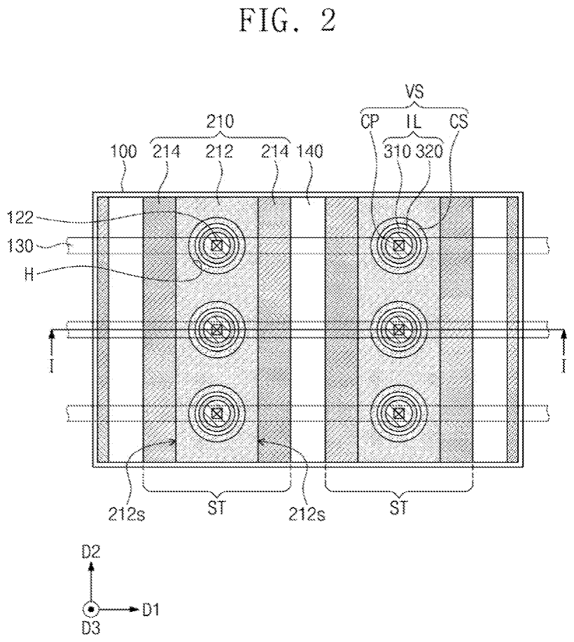

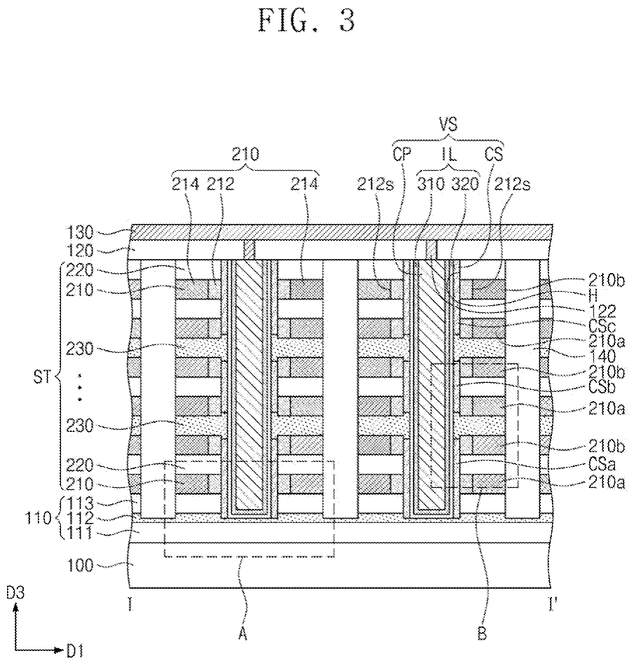

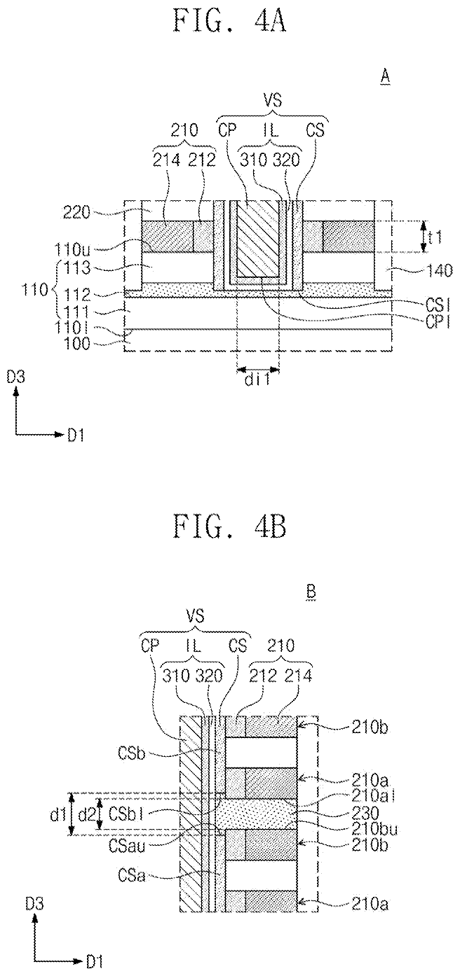

FIG. 2 is a plan view of a semiconductor device according to an embodiment. FIG. 3 is a sectional view taken along a line of FIG. 2. FIGS. 4A and 4B are sectional views of portions ‘A’ and ‘B’, respectively, of FIG. 3.

Referring to FIGS. 2 and 3, a lower insulating layer 110 and stacks ST may be on a substrate 100. The substrate 100 may include a semiconductor substrate or an insulating substrate. In an implementation, the semiconductor substrate may include, e.g., a silicon substrate, a silicon-germanium substrate, a germanium substrate, or a single crystalline epitaxial layer grown in a single-crystalline silicon substrate. In an implementation, the insulating substrate may include, e.g., a sapphire substrate, a glass substrate, or a plastic substrate. As used herein, the term “or” is not an exclusive term, e.g., “A or B” would include A, B, or A and B.

The lower insulating layer 110 may be between the substrate 100 and the stack ST. The lower insulating layer 110 may include a first lower insulating layer 111, a second lower insulating layer 112, and a third lower insulating layer 113. The first and third lower insulating layers 111 and 113 may be formed of or include, e.g., silicon oxide. The second lower insulating layer 112 may be formed of or include an insulating material different from the first and third lower insulating layers 111 and 113. The second lower insulating layer 112 may be formed of or include, e.g., aluminum oxide. The second lower insulating layer 112 may be thinner than the first and third lower insulating layers 111 and 113 (e.g., as measured in the vertical or third direction D3). The second lower insulating layer 112 may have an etch selectivity with respect to the first and third lower insulating layers 111 and 113. The second lower insulating layer 112 may be an etch stop layer.

The stacks ST may be on the lower insulating layer 110. Each of the stacks ST may include electrodes 210, first insulating layers 220, and channel separation patterns 230. The stacks ST may extend (e.g., lengthwise) in the second direction D2 to be parallel to each other. The stacks ST may be spaced apart from each other in the first direction D1. Separation structures 140 may be respectively at both sides of each of the stacks ST. A space between adjacent ones of the stacks ST may be filled with the separation structure 140.

The separation structure 140 may be formed of or include an insulating material (e.g., silicon oxide, silicon nitride, or silicon oxynitride). The separation structure 140 may electrically separate the electrodes 210 in one of the stacks ST from the electrodes 210 in a neighboring one of the stacks ST, and in this case, it may be possible to independently control the stacks ST. The separation structures 140 may extend in the second direction D2 to be parallel to each other. The separation structures 140 may be spaced apart from each other in the first direction D1. Hereinafter, one of the stacks ST will be described in order to reduce complexity in the description and to provide better understanding of an example embodiment.

The electrodes 210 may be stacked in the vertical direction (i.e., the third direction D3). The electrodes 210 may be spaced apart from each other in the third direction D3. Each of the electrodes 210 may be the bit line BL or the source line SL described with reference to FIG. 1. In an implementation, a pair of electrodes 210 (e.g., a first electrode 210a and a second electrode 210b), which are connected in common to one channel layer (e.g., a first channel layer CSa), may correspond to the source line SL and the bit line BL, respectively, described with reference to FIG. 1.

A space between the electrodes 210 may be filled with the first insulating layers 220 or the channel separation patterns 230. The first insulating layers 220 and the channel separation patterns 230 may be formed of or include, e.g., silicon oxide, silicon nitride, or silicon oxynitride.

Each of the electrodes 210 may include a pair of horizontal conductive patterns 214 and a semiconductor pattern 212 therebetween. The semiconductor pattern 212 may extend in the second direction D2. The semiconductor pattern 212 may include opposite side surfaces 212s, which are opposite to each other in the second direction D2. The pair of horizontal conductive patterns 214 may be respectively on the opposite side surfaces 212s of the semiconductor pattern 212. The pair of horizontal conductive patterns 214 may extend along the semiconductor pattern 212, e.g., in the second direction D2.

The semiconductor pattern 212 may be formed of or include a p- or n-type semiconductor material. The semiconductor pattern 212 may be formed of or include polysilicon. In an implementation, the semiconductor pattern 212 may be formed of or include, e.g., n-type doped polysilicon. The semiconductor pattern 212 may enclose a side surface of a vertical structure VS, which will be described below.

The pair of horizontal conductive patterns 214 of the electrode 210 may be spaced apart from each other in the first direction D1, with the semiconductor pattern 212 therebetween. In an implementation, a width of each of the pair of horizontal conductive patterns 214 in the first direction D1 may be smaller than a width of the semiconductor pattern 212 in the first direction D1. The horizontal conductive patterns 214 may be formed of or include, e.g., a metallic material. In an implementation, the horizontal conductive patterns 214 may be formed of or include, e.g., tungsten, copper, or aluminum.

The vertical structures VS may be on the substrate 100. The vertical structures VS may vertically extend in the third direction D3 to penetrate the stack ST. The vertical structures VS may be enclosed by the semiconductor patterns 212. In conjunction with the semiconductor patterns 212, the vertical structures VS may constitute the cell strings CSTR described with reference to FIG. 1. The vertical structures VS may be respectively in vertical holes H, which may penetrate the stack ST in the third direction D3. The vertical structures VS may be arranged in (e.g., spaced apart and aligned along) the second direction D2. The vertical structures VS may include a conductive pillar CP, an interposing layer IL, and a channel structure CS.

Referring to FIGS. 2, 3, and 4A, the conductive pillar CP may vertically extend to penetrate the stack ST. The conductive pillar CP may completely penetrate the stack ST and may extend to or below a level of a bottom surface of the stack ST. A bottom surface CP1 of the conductive pillar CP may be at a level that is lower than (e.g., closer to the substrate 100 in the third direction D3 than) a top surface 110u of the lower insulating layer 110 and may be higher than a bottom surface 1101 of the lower insulating layer 110. In an implementation, the bottom surface CP1 of the conductive pillar CP may be at a level that is higher than a top surface of the second lower insulating layer 112 and is lower than a top surface of the third lower insulating layer 113.

A top surface of the conductive pillar CP may be higher than a top surface of an uppermost one of the electrodes 210 of the stack ST. The top surface of the conductive pillar CP may be at the same level as (e.g., coplanar with) a top surface of an uppermost one of the first insulating layers 220. The conductive pillar CP may have a shape of a circular pillar (e.g., cylindrical). A diameter di1 of the conductive pillar CP may be larger than a thickness t1 of the electrode 210 in the third direction D3. The conductive pillar CP may be formed of or include, e.g., a metal or a semiconductor material. In an implementation, the conductive pillar CP may be formed of or include, e.g., tungsten, copper, or titanium. In an implementation, the conductive pillar CP may be formed of or include, e.g., polysilicon.

The channel structure CS may be between the conductive pillar CP and the electrodes 210. As shown in FIG. 2, the channel structure CS may enclose the conductive pillar CP. An inner side surface of the channel structure CS may be spaced apart from an outer side surface of the conductive pillar CP, e.g., by or with a ferroelectric layer 310 and a gate insulating layer 320 therebetween.

An outer side surface of the channel structure CS may be in contact (e.g., direct contact) with the electrodes 210. The channel structure CS may be selectively used as a charge conduction path between the electrodes 210, which are connected to the channel structure CS, when an electric signal is applied to the conductive pillar CP.

The channel structure CS may cover a portion of an outer side surface of the gate insulating layer 320. In an implementation, the channel structure CS may not fully cover an outer side surface of the interposing layer IL. Another portion of the outer side surface of the interposing layer IL may be covered with the channel separation patterns 230.

A lower portion of the channel structure CS may be buried in the lower insulating layer 110. As shown in FIG. 4A, a bottom surface CS1 of the channel structure CS may be at a level lower than the bottom surface CP1 of the conductive pillar CP. The bottom surface CS1 of the channel structure CS may be at a vertical level between the top surface 110u and the bottom surface 1101 of the lower insulating layer 110. The bottom surface CS1 of the channel structure CS may be in contact with the second lower insulating layer 112.

A top surface of the channel structure CS may be at the same vertical level as the top surface of the conductive pillar CP. The top surface of the channel structure CS may be coplanar with the top surface of the uppermost one of the first insulating layers 220 of the stack ST. A thickness of the channel structure CS may be larger than a thickness of the gate insulating layer 320. In an implementation, the thickness of the channel structure CS may range from, e.g., 5 nm to 10 nm.

The channel structure CS may be formed of or include, e.g., a semiconductor material, an amorphous oxide semiconductor material, or a two-dimensional material. In an implementation, the channel structure CS may be formed of or include, e.g., polysilicon, doped silicon (Si), silicon germanium (SiGe), or a semiconductor material formed by a selective epitaxial growth (SEG) process.

In an implementation, the channel structure CS may be formed of or include, e.g., an amorphous oxide semiconductor material. In an implementation, the channel structure CS may be formed of or include a compound including oxygen (O) and at least two of zinc (Zn), indium (In), gallium (Ga), and tin (Sn). In an implementation, the channel structure CS may be formed of or include, e.g., indium gallium zinc oxide (IGZO) or indium tin zinc oxide (ITZO).

In an implementation, the channel structure CS may be formed of or include, e.g., a two-dimensional material. In an implementation, the channel structure CS may include, e.g., a metal chalcogenide, a transition metal chalcogenide, graphene, or phosphorene. The metal chalcogenide or transition metal chalcogenide may be a metal compound, which may be represented by the chemical formula of MX_{y}, in which y is an integer (e.g., 1, 2, or 3). In the chemical formula, M may be a metal atom or a transition metal atom and may include, e.g., W, Mo, Ti, Zn, Zs, or Zr. In the chemical formula, X may be a chalcogen atom and may include, e.g., S, Se, O, or Te. In an implementation, the channel structure CS may include, e.g., graphene, phosphorene, MoS₂, MoSe₂, MoTe₂, W₅₂, WSe₂, WTe₂, ReS₂, ReSe₂, TiS₂, TiSe₂, TiTe₂, ZnO, ZnS₂, ZsSe₂, WO₃, or MoO₃. The channel structure CS may have a mono-layered structure or a multi-layered structure, in which 2 to 100 layers are stacked. The multi-layered structure may be realized using at least one pair of monolayers that are coupled by a Van der Waals force.

The interposing layer IL may be between the channel structure CS and the conductive pillar CP. The interposing layer IL may enclose a side surface of the conductive pillar CP and may cover the bottom surface CP1 of the conductive pillar CP. The interposing layer IL may separate the conductive pillar CP from the channel structure CS. The interposing layer IL may include the ferroelectric layer 310 and the gate insulating layer 320.

The ferroelectric layer 310 may be between the conductive pillar CP and the channel structure CS. The ferroelectric layer 310 may enclose the conductive pillar CP. The ferroelectric layer 310 may be configured to have various polarization states, depending on a voltage difference between the conductive pillar CP and the electrodes 210. The ferroelectric layer 310 may be formed of or include a ferroelectric material. The ferroelectric layer 310 may include, e.g., a hafnium compound having a ferroelectric property. In an implementation, the ferroelectric layer 310 may be formed of or include, e.g., HfO₂, HfZnO, HfSiO, HfSiON, HfTaO, HfTiO, HfZrO, or combinations thereof. The ferroelectric layer 310 may have an orthorhombic phase. A dielectric constant of the ferroelectric layer 310 may be higher than a dielectric constant of the gate insulating layer 320.

The ferroelectric layer 310 may cover the outer side surface and the bottom surface CP1 of the conductive pillar CP. The ferroelectric layer 310 may not cover the top surface of the conductive pillar CP. A top surface of the ferroelectric layer 310 may be at the same level as the top surface of the conductive pillar CP. The ferroelectric layer 310 may have a half-opened pipe shape with closed bottom and opened top. A thickness of the ferroelectric layer 310 may be larger than a thickness of the gate insulating layer 320. In an implementation, the thickness of the ferroelectric layer 310 may range from, e.g., 5 nm to 20 nm.

The gate insulating layer 320 may be between the ferroelectric layer 310 and the electrodes 210. In an implementation, the gate insulating layer 320 may be formed of or include, e.g., silicon oxide, silicon oxynitride, a high-k dielectric material having a higher dielectric constant than silicon oxide, or combinations thereof. The high-k dielectric material may be formed of or include, e.g., a metal oxide or a metal oxynitride.

The thickness of the gate insulating layer 320 may be smaller than a thickness of the ferroelectric layer 310 and the channel structure CS. In an implementation, the thickness of the gate insulating layer 320 may range from, e.g., 0.5 nm to 5 nm. The gate insulating layer 320 may cover an outer side surface and a bottom surface of the ferroelectric layer 310. The ferroelectric layer 310 may have a half-opened pipe shape with closed bottom and opened top. The bottom surface of the ferroelectric layer 310 may be at a level between top and bottom surfaces of the second lower insulating layer 112. The top surface of the ferroelectric layer 310 may be at the same level as the top surface of the conductive pillar CP.

Referring back to FIGS. 1 to 3, the channel structure CS may include channel layers CSa, CSb, and CSc, which are vertically spaced apart from each other. In an implementation, the channel layers CSa, CSb, and CSc may include a first channel layer CSa, a second channel layer CSb, and a third channel layer CSc. The first to third channel layers CSa, CSb, and CSc may be electrically separated from each other. The first to third channel layers CSa, CSb, and CSc may be respectively in different ones of the unit cells UC.

In an implementation, the electrodes 210 may include the first and second electrodes 210a and 210b, which are connected to the channel layer CSa, CSb, or CSc. The first and second electrodes 210a and 210b may be alternately and repeatedly stacked. Each of the first to third channel layers CSa, CSb, and CSc may connect the pair of first and second electrodes 210a and 210b, which are adjacent to each other in the third direction D3, to each other.

In an implementation, the first electrodes 210a may correspond to the source lines SL of FIG. 1, respectively, and the second electrodes 210b may correspond to the bit lines BL of FIG. 1, respectively. In an implementation, the first electrodes 210a may correspond to the bit lines BL of FIG. 1, respectively, and the second electrodes 210b may correspond to the source lines SL of FIG. 1, respectively.

The first and second electrodes 210a and 210b, which are connected to the channel layer CSa, CSb, or CSc, may be a source electrode and a drain electrode, respectively. Accordingly, the source electrode and the drain electrode may be electrically connected to or disconnected from each other through the channel layer by an electric signal applied to the conductive pillar CP.

Each of the first to third channel layers CSa, CSb, and CSc may be a pipe-shaped pattern with opened top and bottom (e.g., a hollow, open cylinder). The first channel layer CSa may enclose a lower portion of the outer side surface of the gate insulating layer 320. A bottom surface of the first channel layer CSa may be lower than a bottom surface of the lowermost one of the electrodes 210. The second channel layer CSb may enclose a center portion of the outer side surface of the gate insulating layer 320. The third channel layer CSc may enclose an upper portion of the outer side surface of the gate insulating layer 320. A top surface of the third channel layer CSc may be higher than the top surface of the uppermost one of the electrodes 210.

The channel separation patterns 230 may be respectively between the first and second channel layers CSa and CSb and between the second and third channel layers CSb and CSc. Each of the channel separation patterns 230 may be between the first electrode 210a of one unit cell UC and the second electrode 210b of another (e.g., adjacent) unit cell UC. The channel separation patterns 230 may divide the channel structure CS into the first to third channel layers CSa, CSb, and CSc. The first to third channel layers CSa, CSb, and CSc may be electrically disconnected from each other by or due to the channel separation patterns 230 therebetween.

Referring to FIGS. 2, 3, and 4B, the channel separation pattern 230 may be between the first and second electrodes 210a and 210b, which are respectively connected to the second channel layer CSb and the first channel layer CSa. The channel separation pattern 230 may be between the first and second channel layers CSa and CSb, which are adjacent to each other in the third direction D3.

A distance d1 (in the third direction D3) between a top surface CSau of the first channel layer CSa and a bottom surface CSb1 of the second channel layer CSb may be larger than a distance d2 (in the third direction D3) between a top surface 210bu of the second electrode 210b and a bottom surface 210a1 of the first electrode 210a. In an implementation, a thickness, in the third direction D3, of a portion of the channel separation pattern 230 that is between the first and second channel layers CSa and CSb may be larger than a thickness, in the third direction D3, of a portion of the channel separation pattern 230 that is between the first and second electrodes 210a and 210b. The thickness of the channel separation pattern 230 in the third direction D3 may have the largest value d1 between the top surface CSau of the first channel layer CSa and the bottom surface CSb1 of the second channel layer CSb.

Referring back to FIGS. 2 and 3, an upper insulating layer 120 may be on the stack ST. The upper insulating layer 120 may cover top surfaces of the vertical structures VS and top surfaces of the separation structures 140. In an implementation, the upper insulating layer 120 may be formed of or include, e.g., silicon oxide, silicon nitride, or silicon oxynitride.

Conductive lines 130 may be on the upper insulating layer 120. The conductive lines 130 may extend in the first direction D1. The conductive lines 130 may be arranged in the second direction D2. Each of the conductive lines 130 may connect the vertical structures VS, which are in different ones of the stack ST, to each other. The conductive lines 130 may correspond to the word lines WL described with reference to FIG. 1.

The conductive line 130 may be electrically connected to the conductive pillar CP through a contact plug 122 penetrating the upper insulating layer 120. The contact plug 122 may be on the top surface of the conductive pillar CP and may have a width smaller than the conductive pillar CP. The contact plug 122 may be electrically disconnected or isolated from the ferroelectric layer 310 and the channel structure CS.

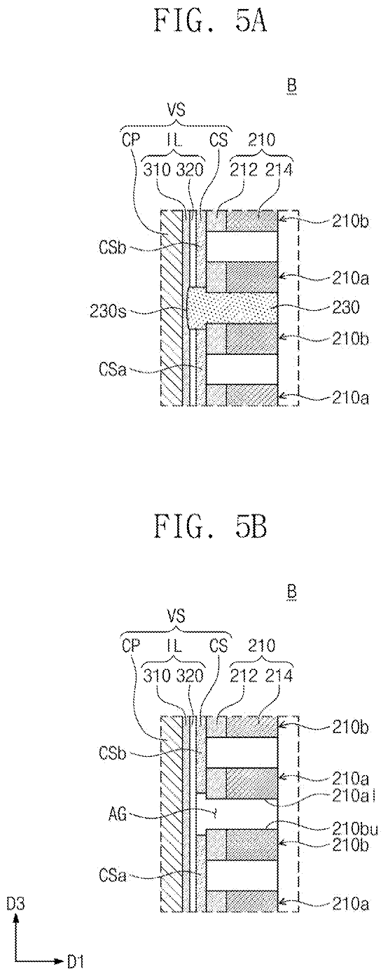

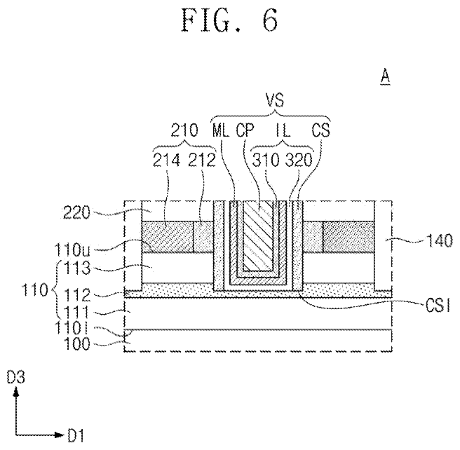

FIGS. 5A and 5B are enlarged sectional views of a portion (e.g., ‘B’ of FIG. 3) of a semiconductor device according to an embodiment. FIG. 6 is an enlarged sectional view of a portion (e.g., ‘A’ of FIG. 3) of a semiconductor device according to an embodiment. In the following description of the present embodiment, an element or step previously described with reference to FIGS. 1 to 4B may be identified by a similar or identical reference number without repeating an overlapping description thereof.

Referring to FIG. 5A, the channel separation pattern 230 may penetrate the channel structure CS and the gate insulating layer 320 and may be in contact with the ferroelectric layer 310. A side surface 230s of the channel separation pattern 230 may protrude convexly toward the conductive pillar CP. In an implementation, the ferroelectric layer 310 may have a recessed portion that is recessed (e.g., inwardly) toward the conductive pillar CP. The recessed portion of the ferroelectric layer 310 may correspond (e.g., be complementary) to the convex side surface 230s of the channel separation pattern 230.

Referring to FIG. 5B, an air gap AG may be between the first electrode 210a connected to the second channel layer CSb and the second electrode 210b connected to the first channel layer CSa. The air gap AG may also be between the first and second channel layers CSa and CSb. The air gap AG may be formed by omitting the channel separation pattern 230 previously described with reference to FIG. 4B. Accordingly, the air gap AG may have substantially the same shape as the channel separation pattern 230 described above.

The air gap AG may have a relatively low dielectric constant, and it may be possible to reduce a coupling capacitance between adjacent ones of the electrodes 210, that could otherwise be caused by a crosstalk phenomenon therebetween. If there were the air gap AG, to reduce the capacitance between the electrodes 210, it could be necessary to increase a thickness of the channel separation pattern 230. In an implementation, the air gap AG having a low dielectric constant may be between the electrodes 210, and it may be possible to reduce a distance between the electrodes 210. As a result, it may be possible to reduce a height of the stack ST or to form more unit cells UC in the stack ST. In an implementation, it may be possible to increase an integration density of the semiconductor device.

Referring to FIG. 6, the vertical structure VS may further include a metal layer ML between the ferroelectric layer 310 and the gate insulating layer 320.

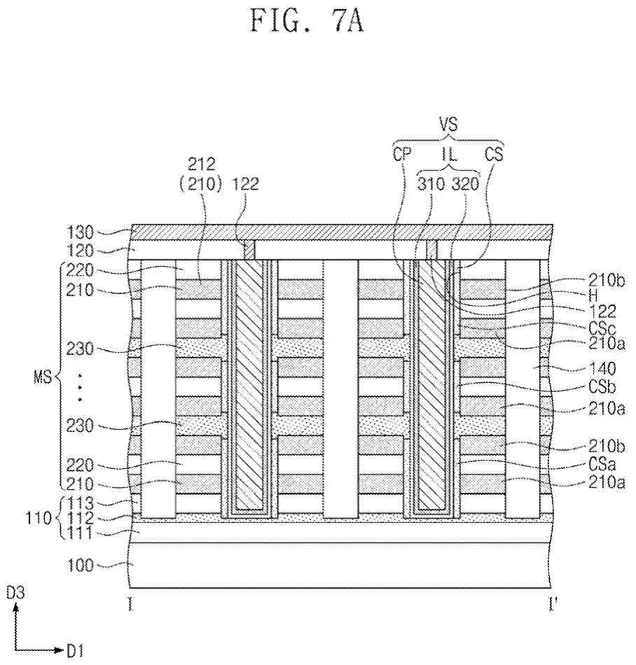

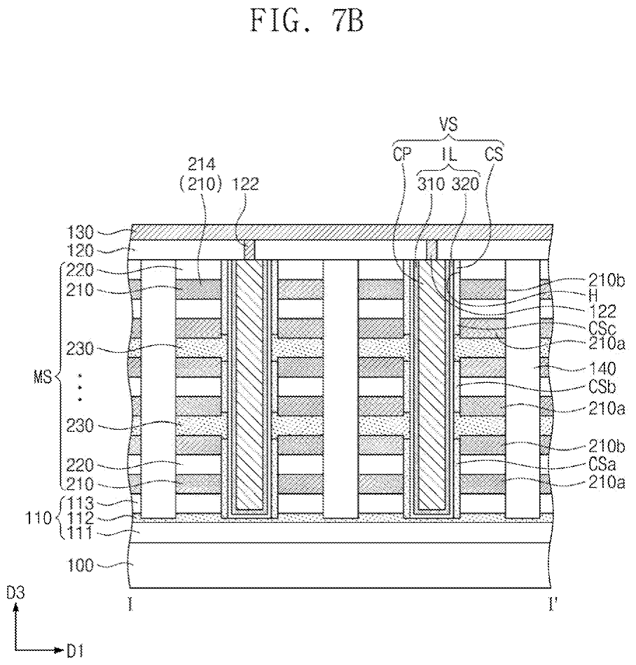

FIGS. 7A and 7B are sectional views, each of which is taken along a line I-I′ of FIG. 2 of a semiconductor device according to an embodiment.

In an implementation, referring to FIG. 7A, each of the electrodes 210 may be composed of the semiconductor pattern 212. The electrode 210 may include only the semiconductor pattern 212, and the pair of horizontal conductive patterns 214 described with reference to FIGS. 2 and 3 may be omitted. The semiconductor pattern 212 may be in contact with the separation structures 140. The semiconductor pattern 212 may be a line-shaped pattern extending in the second direction D2.

In an implementation, referring to FIG. 7B, each of the electrodes 210 may be composed of the horizontal conductive pattern 214. The electrode 210 may include only the horizontal conductive pattern 214, and the semiconductor pattern 212 described with reference to FIGS. 2 and 3 may be omitted. In an implementation, the electrode 210 may be formed of only a metallic material without a semiconductor material. The horizontal conductive pattern 214 may be a line-shaped pattern extending in the second direction D2. The horizontal conductive pattern 214 may be in direct contact with the channel structure CS.

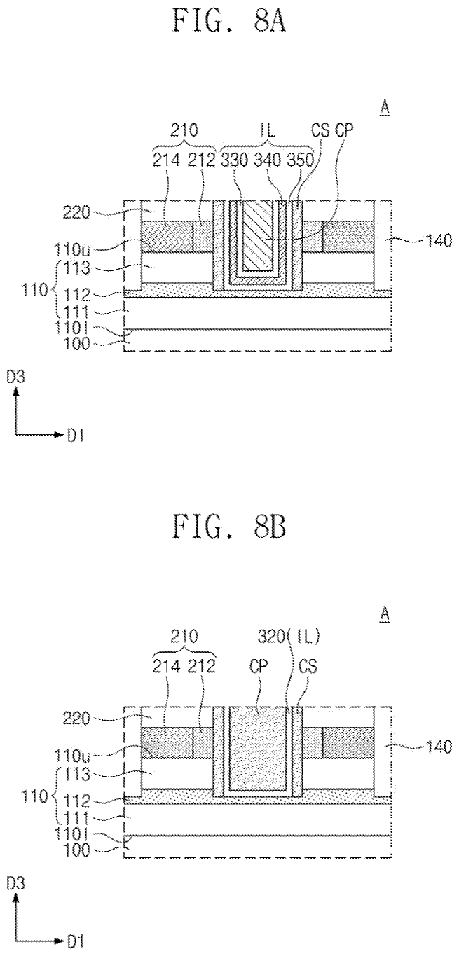

FIGS. 8A and 8B are enlarged sectional views of a portion (e.g., ‘A’ of FIG. 3) of a semiconductor device according to an embodiment.

Referring to FIG. 8A, the interposing layer IL may include a blocking insulating layer 330, a charge storing layer 340, and a tunnel insulating layer 350, which are sequentially (e.g., outwardly) stacked between the conductive pillar CP and the channel structure CS. The semiconductor device according to the present embodiment may be a NOR FLASH memory device. The interposing layer IL may be a data storing layer of the NOR FLASH memory device.

The charge storing layer 340 may be a trap insulating layer, a floating gate electrode, or an insulating layer including conductive nanodots. In an implementation, the charge storing layer 340 may include, e.g., a silicon nitride layer, a silicon oxynitride layer, a silicon-rich nitride layer, a nanocrystalline silicon layer, or a laminated trap layer. In an implementation, the charge storing layer 340 may be formed of or include a high-k dielectric material, e.g., aluminum oxide, hafnium oxide, yttrium oxide, lanthanum oxide, or zirconium oxide.

The blocking insulating layer 330 may be between the conductive pillar CP and the charge storing layer 340. The blocking insulating layer 330 may include a silicon oxide layer. The tunnel insulating layer 350 may be between the channel structure CS and the charge storing layer 340. The tunnel insulating layer 350 may include a silicon oxide layer.

In an implementation, the tunnel insulating layer 350 of the interposing layer IL may be omitted. In this case, the charge storing layer 340 may be in direct contact with the channel structure CS. The semiconductor device of the present embodiment, from which the tunnel insulating layer 350 has been omitted, may be a trapping DRAM device.

Referring to FIG. 8B, the interposing layer IL may include only the gate insulating layer 320. In an implementation, the ferroelectric layer 310 previously described with reference to FIGS. 2 and 3 may be omitted from the interposing layer IL. In an implementation, the gate insulating layer 320 may be in direct contact with the channel structure CS as well as the conductive pillar CP.

The semiconductor device according to the present embodiment may be a capacitor-less IT DRAM. The semiconductor device (i.e., the IT DRAM) in the present embodiment may have states of “1” and “0”, using a threshold voltage difference (ΔVth) caused by a floating body effect. The semiconductor device may have a floating body structure, and it may be possible to detect a variation in threshold voltage (Vth) that is caused by a body potential.

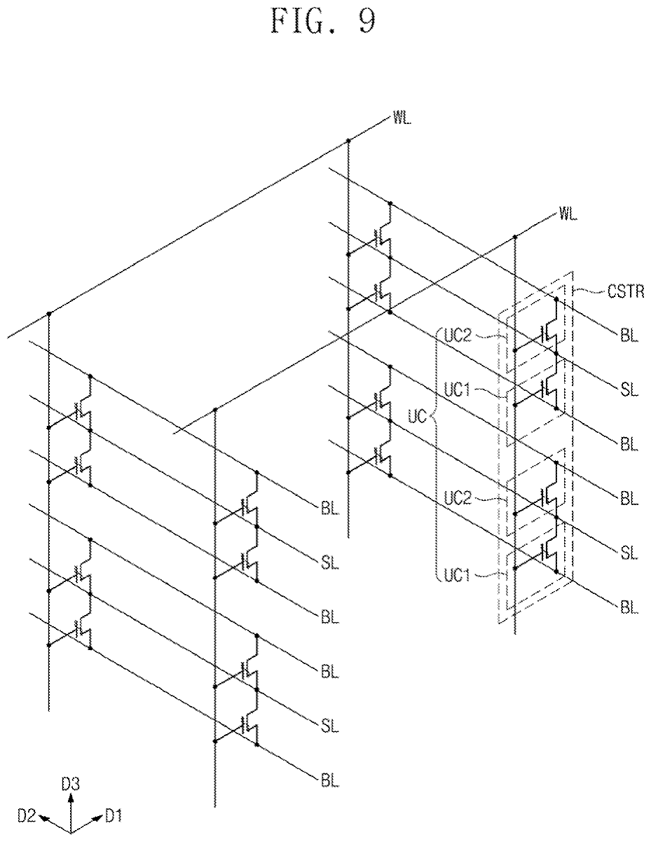

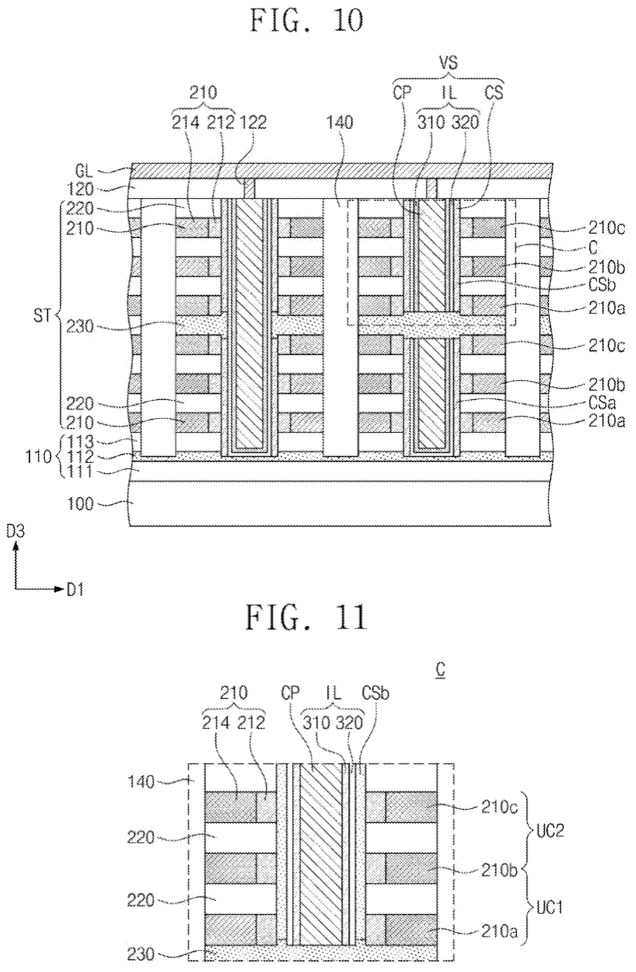

FIG. 9 is a circuit diagram of a semiconductor device according to an embodiment. FIG. 10 is a sectional view of a semiconductor device according to an embodiment. FIG. 11 is an enlarged sectional view of a portion ‘C’ of FIG. 10. In the following description of the present embodiment, an element or step previously described with reference to FIGS. 1 to 4B may be identified by a similar or identical reference number without repeating an overlapping description thereof.

Referring to FIG. 9, the unit cells UC of the cell string CSTR may include first and second unit cells UC1 and UC2. The first unit cell UC1 and the second unit cell UC2 may be adjacent to each other in the third direction D3. A memory transistor of the first unit cell UC1 and a memory transistor of the second unit cell UC2 may be configured to share a source terminal.

The first and second unit cells UC1 and UC2 may be respectively connected to different ones of the bit lines BL. In an implementation, the first and second unit cells UC1 and UC2 may be connected to one of the source lines SL. The source line SL, which is connected to the first and second unit cells UC1 and UC2, may serve as a common source line.

Referring to FIG. 10, the channel structure CS may include the first and second channel layers CSa and CSb. The channel separation pattern 230 may be between the first and second channel layers CSa and CSb. A first electrode 210a, a second electrode 210b, and a third electrode 210c may be on each of the first and second channel layers CSa and CSb. The first to third electrodes 210a, 210b, and 210c may be sequentially stacked (e.g., in the third direction D3).

Referring to FIG. 11, the first to third electrodes 210a, 210b, and 210c, which are stacked, may enclose the second channel layer CSb. The second channel layer CSb and the first to third electrodes 210a, 210b, and 210c may constitute the first unit cell UC1 and the second unit cell UC2, which are (vertically) adjacent to each other, of FIG. 9. The first and third electrodes 210a and 210c may correspond to respective ones of the bit lines BL of FIG. 9. The second electrode 210b may correspond to the source line SL of FIG. 9.

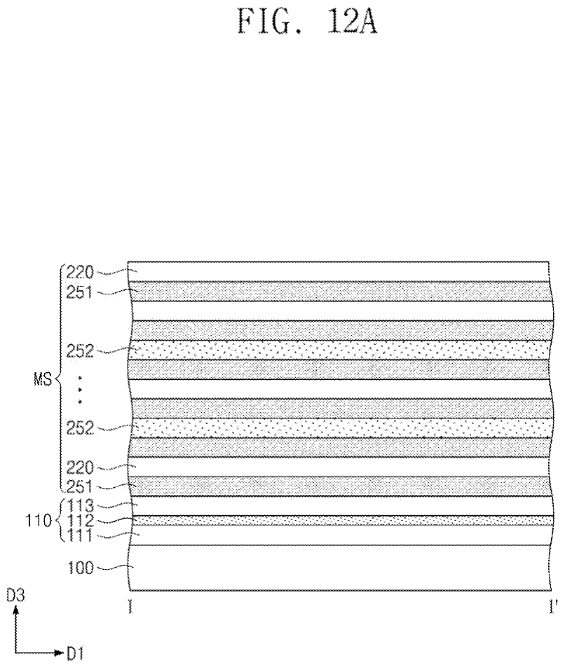

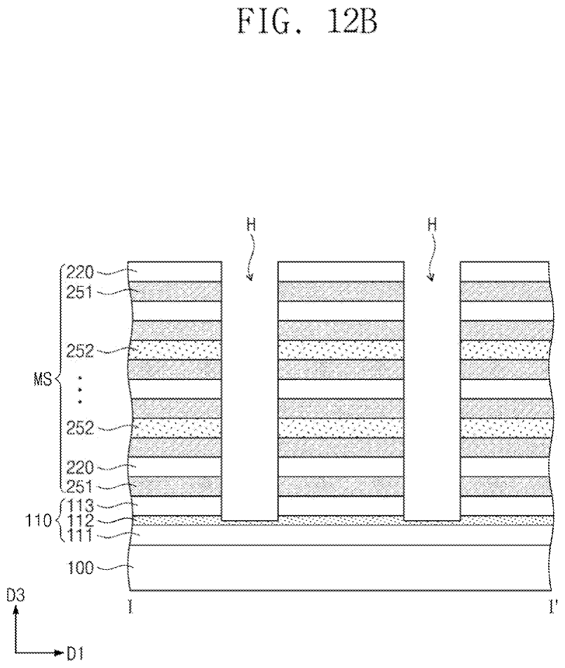

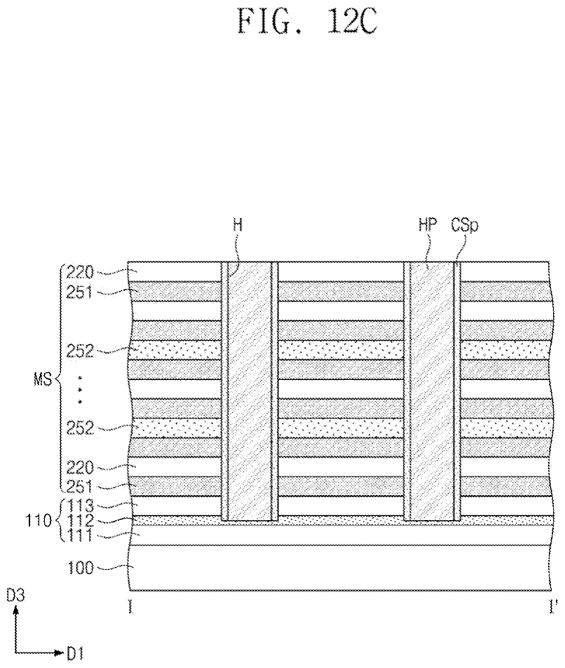

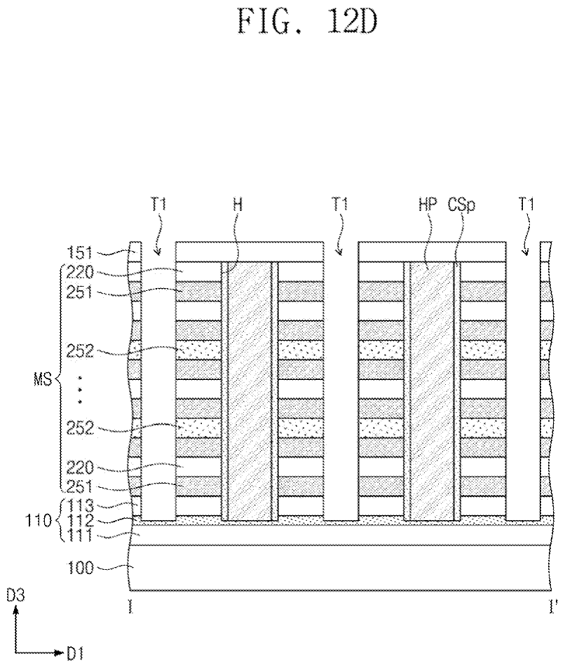

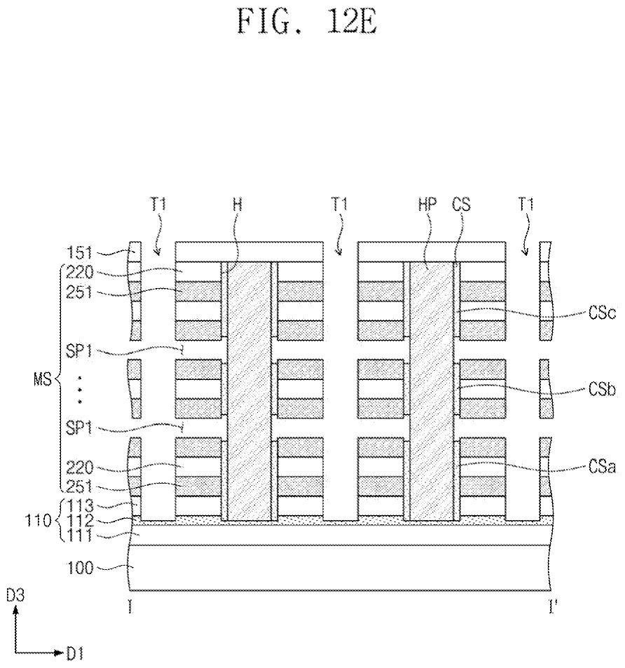

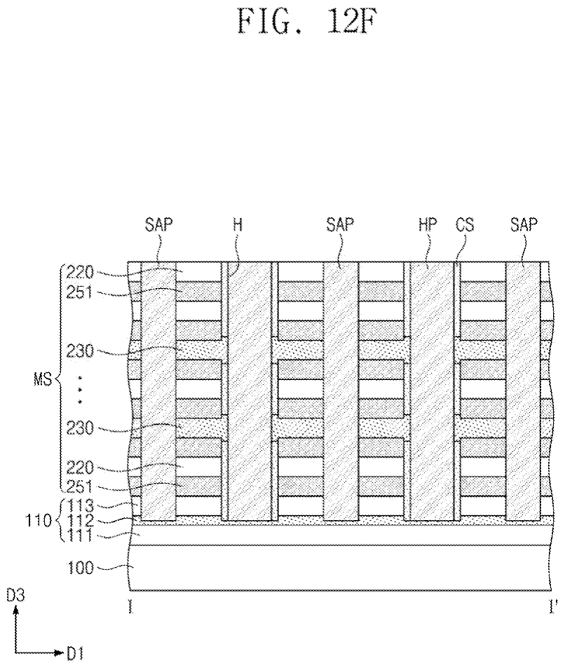

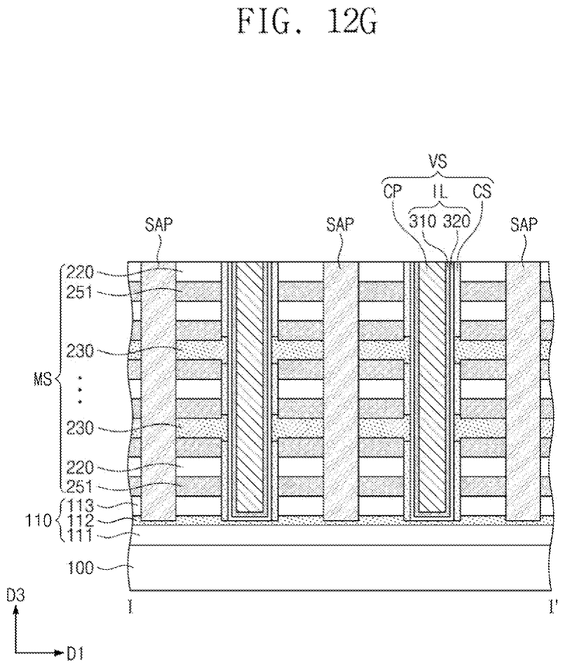

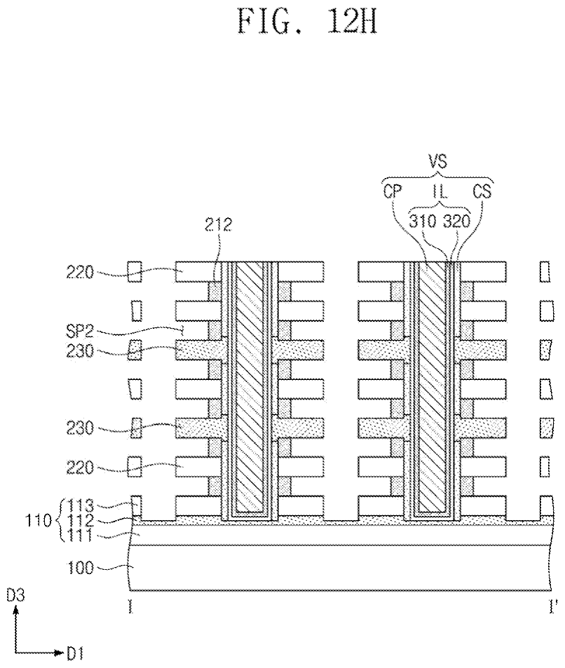

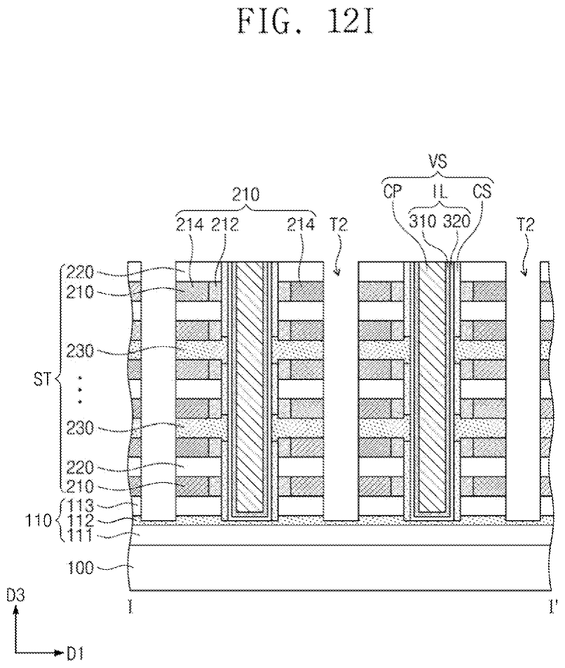

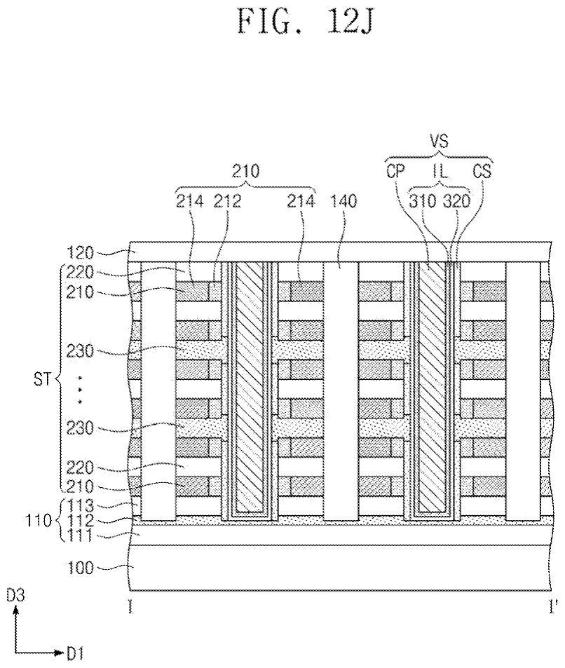

FIGS. 12A to 12J are sectional views, which are taken along the line I-I′ of FIG. 2 of stages in a method of fabricating a semiconductor device according to an embodiment.

Referring to FIG. 12A, a lower insulating layer 110 may be formed on a substrate 100. The formation of the lower insulating layer 110 may include sequentially forming a first lower insulating layer 111, a second lower insulating layer 112, and a third lower insulating layer 113 on the substrate 100. The first and third lower insulating layers 111 and 113 may be formed of or include, e.g., silicon oxide. The second lower insulating layer 112 may be formed of or include a material (e.g., aluminum oxide) that can be used as an etch stop layer.

A mold structure MS may be formed on the lower insulating layer 110. The formation of the mold structure MS may include forming a semiconductor layer 251, forming a first insulating layer 220 on the semiconductor layer 251, forming another semiconductor layer 251 on the first insulating layer 220, and a second insulating layer 252 on the semiconductor layer 251. The mold structure MS may be formed by repeatedly forming the semiconductor layer 251, the first insulating layer 220, the semiconductor layer 251, and the second insulating layer 252.

The semiconductor layer 251 may be formed of doped polysilicon. In an implementation, the semiconductor layer 251 may be formed of an n-type polysilicon layer. The first insulating layer 220 may be formed of or include silicon oxide. The second insulating layer 252 may be formed of or include silicon nitride.

Referring to FIG. 12B, the mold structure MS may be patterned to form a plurality of vertical holes H penetrating the mold structure MS. The patterning of the mold structure MS may include forming a hard mask pattern on the mold structure MS using a photolithography process and performing an anisotropic etching process on the mold structure MS using the hard mask pattern as an etch mask. The hard mask pattern may be selectively removed.

A bottom of each of the vertical holes H may be at a level between top and bottom surfaces of the second lower insulating layer 112. In an implementation, the second lower insulating layer 112 may be used as an etch stop layer in the anisotropic etching process. Each of the vertical holes H may have a circular cylinder shape.

Referring to FIG. 12C, a channel pillar CSp and a sacrificial pillar HP may be formed in each of the vertical holes H. The channel pillar CSp may be formed to enclose an outer side surface of the sacrificial pillar HP. The channel pillar CSp may be formed of or include, e.g., a semiconductor material, an amorphous oxide semiconductor material, or a two-dimensional material.

In an implementation, the channel pillar CSp may include polysilicon, an amorphous oxide semiconductor material, or a two-dimensional material, which is formed by a deposition process. In this case, it may be possible to reduce a process difficulty in a process of forming the channel pillar CSp.

Referring to FIG. 12D, a mask pattern 151 may be formed on the mold structure MS. The mask pattern 151 may cover the channel pillar CSp and the sacrificial pillar HP, which are in each of the vertical holes H.

An anisotropic etching process using the mask pattern 151 as an etch mask may be performed on the mold structure MS to form a plurality of first trenches T1 penetrating the mold structure MS. The first trenches T1 may extend in a second direction D2 to be parallel to each other. The first trenches T1 may be spaced apart from each other in a first direction D1. The mold structure MS may be divided into a plurality of mold structures MS, which are separated from each other in the first direction D1, by the first trenches T1. The first insulating layer 220 may be divided into a plurality of first insulating layers 220.

Referring to FIG. 12E, first empty spaces SP1 may be formed by selectively removing the second insulating layers 252 exposed through the first trench T1. A portion of the channel pillar CSp may be exposed to the first trench T1 through the first empty space SP1.

First to third channel layers CSa, CSb, and CSc, which are separated from each other, may be formed by selectively removing the exposed portion of the channel pillar CSp. The first to third channel layers CSa, CSb, and CSc may be formed by vertically cutting a single channel pillar CSp. The first to third channel layers CSa, CSb, and CSc may constitute a channel structure CS.

Referring to FIG. 12F, channel separation patterns 230 may be formed by filling the first empty spaces SP1 with an insulating material. The channel separation patterns 230 may be formed in the first empty spaces SP1, respectively.

Sacrificial patterns SAP may be formed by filling the first trenches T1 with an insulating material. The sacrificial patterns SAP may be formed in the first trenches T1, respectively. When viewed in a plan view, each of the sacrificial patterns SAP may be a line-shaped pattern extending in the first direction D1.

Referring to FIG. 12G, the sacrificial pillar HP may be replaced with a conductive pillar CP and an interposing layer IL. In an implementation, the sacrificial pillar HP may be selectively removed. Thereafter, the interposing layer IL and the conductive pillar CP may be sequentially formed in the vertical hole, from which the sacrificial pillar HP has been removed.

The formation of the interposing layer IL may include sequentially forming a gate insulating layer 320 and a ferroelectric layer 310. The formation of the conductive pillar CP may include forming a conductive material to fill the vertical hole provided with the ferroelectric layer 310. The conductive pillar CP, the interposing layer IL, and the channel structure CS may constitute the vertical structure VS.

Referring to FIG. 12H, the sacrificial patterns SAP may be selectively removed. In an implementation, the sacrificial patterns SAP may be removed, and the semiconductor layers 251 may be exposed (e.g., to the outside). Second empty spaces SP2 may be formed by partially removing the exposed semiconductor layers 251. A portion of the semiconductor layer 251, which is not removed, may remain to form a semiconductor pattern 212. The semiconductor pattern 212 may be locally left around only the channel structure CS.

Referring to FIG. 12I, a metal layer may be formed to fill the second empty spaces SP2. The metal layer may be formed to cover opposite side surfaces of the semiconductor pattern 212. The metal layer may also cover side surfaces of the first insulating layers 220 that are vertically stacked. A plurality of horizontal conductive patterns 214 may be formed from the metal layer by performing a wet etching process of selectively etching the metal layer. The horizontal conductive patterns 214 may be formed in the second empty spaces SP2, respectively. A second trench T2 may be formed by removing a portion of the metal layer.

In an implementation, the portion of the metal layer may be removed, and a pair of horizontal conductive patterns 214 may be respectively formed at both sides of the semiconductor pattern 212. The semiconductor pattern 212 and the pair of horizontal conductive patterns 214 may constitute an electrode 210. The electrodes 210 and the first insulating layers 220 may be alternately stacked to form a stack ST.

Referring to FIG. 12J, separation structures 140 may be formed in the second trenches T2, respectively. The separation structure 140 may be between adjacent ones of the stacks ST. An upper insulating layer 120 may be formed on the stacks ST and the separation structures 140.

Referring back to FIG. 3, conductive lines 130 may be formed on the upper insulating layer 120. A contact plug 122 may be formed to connect the conductive line 130 to the conductive pillar CP of the vertical structure VS.

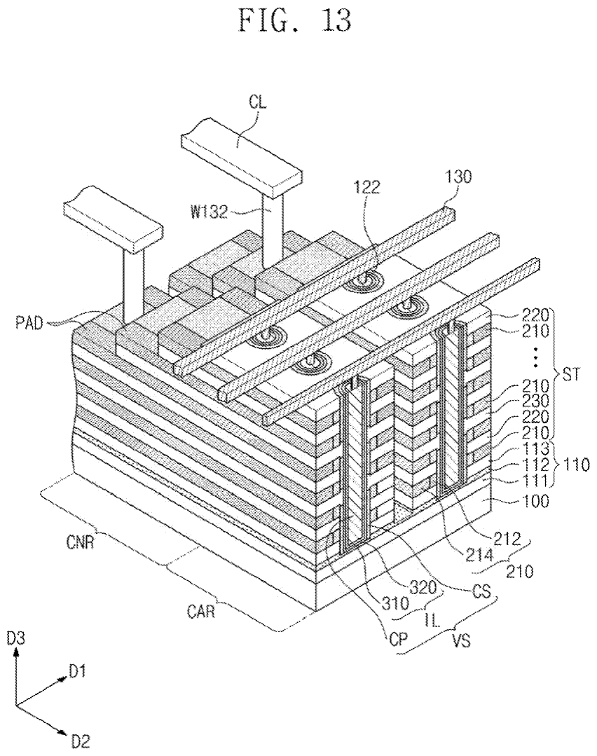

FIG. 13 is a perspective view of a semiconductor device according to an embodiment.

Referring to FIG. 13, the substrate 100 may include a cell array region CAR and a pad region CNR. The stacks ST and the vertical structures VS previously described with reference to FIGS. 2 and 3 may be on the cell array region CAR.

The electrodes 210 of each of the stacks ST may extend onto the pad region CNR. The electrodes 210 on the pad region CNR may form a stepwise structure. In an implementation, the electrodes 210 on the pad region CNR may include pads PAD, which are arranged in a stepwise shape.

The pads PAD may be exposed to the outside of the stack ST in a sequential or stepwise manner. An electrode contact W132 may be on and connected to the exposed pad PAD. A metal line CL may be on and connected to the electrode contact W132. A voltage or signal may be applied to the electrode 210, which may be the bit line BL or the source line SL, through the metal line CL.

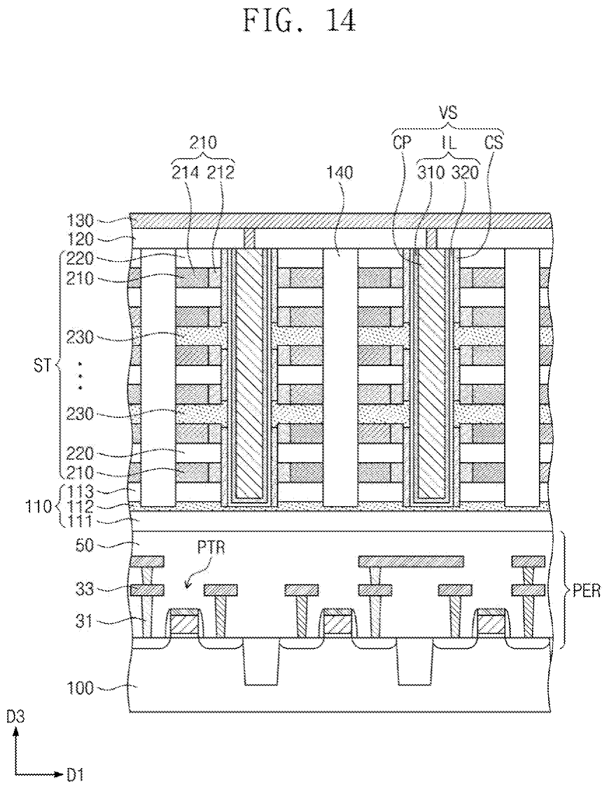

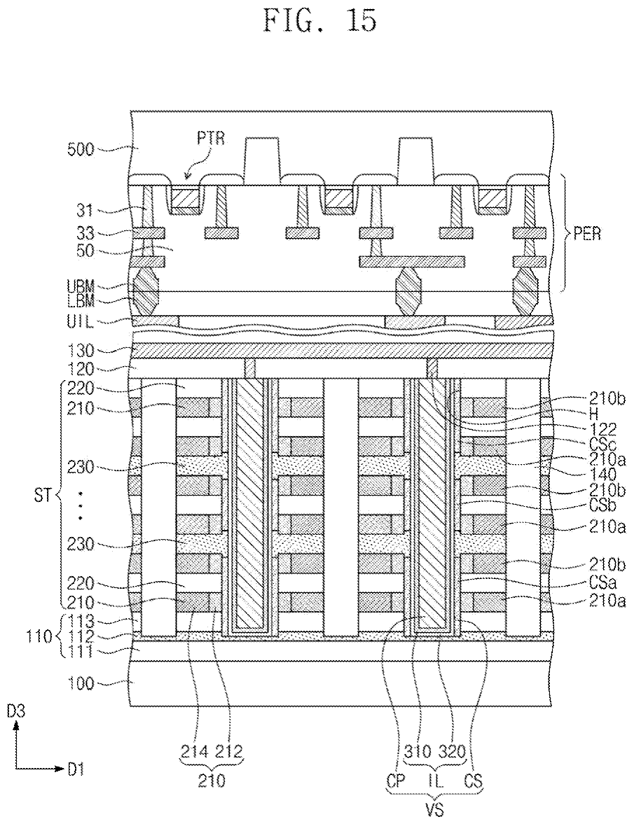

FIGS. 14, 15, and 16 are sectional views of a semiconductor device according to an embodiment.

Referring to FIG. 14, a peripheral circuit layer PER may be on the substrate 100. The peripheral circuit layer PER may be between the substrate 100 and the lower insulating layer 110. In an implementation, the peripheral circuit layer PER may be below a memory cell array layer, which is composed of the stacks ST. The semiconductor device according to the present embodiment may have a cell-on-peri (COP) structure.

The peripheral circuit layer PER may include a plurality of peripheral transistors PTR and a plurality of peripheral interconnection lines 33, which are on the substrate 100. The peripheral transistors PTR and the peripheral interconnection lines 33 may be covered with an interlayer insulating layer 50. The peripheral interconnection lines 33 may be on the peripheral transistors PTR and may be connected to the peripheral transistors PTR through contacts 31.

In an implementation, the peripheral circuit layer PER may include sense amplifiers, row decoders, or sub-word line drivers, which are electrically connected to the memory cell array layer.

Referring to FIG. 15, a peripheral circuit layer PER and an upper substrate 500 may be on the memory cell array layer composed of the stacks ST. The peripheral circuit layer PER may be substantially the same as described with reference to FIG. 14. The semiconductor device according to the present embodiment may have a chip-to-chip (C2C) structure.

The peripheral circuit layer PER may face the substrate 100. In an implementation, the upper substrate 500 may be at a level higher than the peripheral circuit layer PER and may be exposed to the outside. Upper interconnection lines UIL and lower bonding metals LBM may be in the uppermost portion of the memory cell array layer. The lower bonding metals LBM may be on the upper interconnection lines UIL, respectively.

Upper bonding metals UBM may be in the lowermost portion of the peripheral circuit layer PER. The upper bonding metals UBM may be connected to the peripheral interconnection lines 33, respectively. Each of the lower bonding metals LBM may be connected to a corresponding one of the upper bonding metals UBM in a metal bonding manner. In an implementation, the metal bonding manner may be a Cu—Cu bonding manner. The lower bonding metal LBM may be connected to the upper bonding metal UBM, and the memory cell array layer may be connected to the peripheral circuit layer PER.

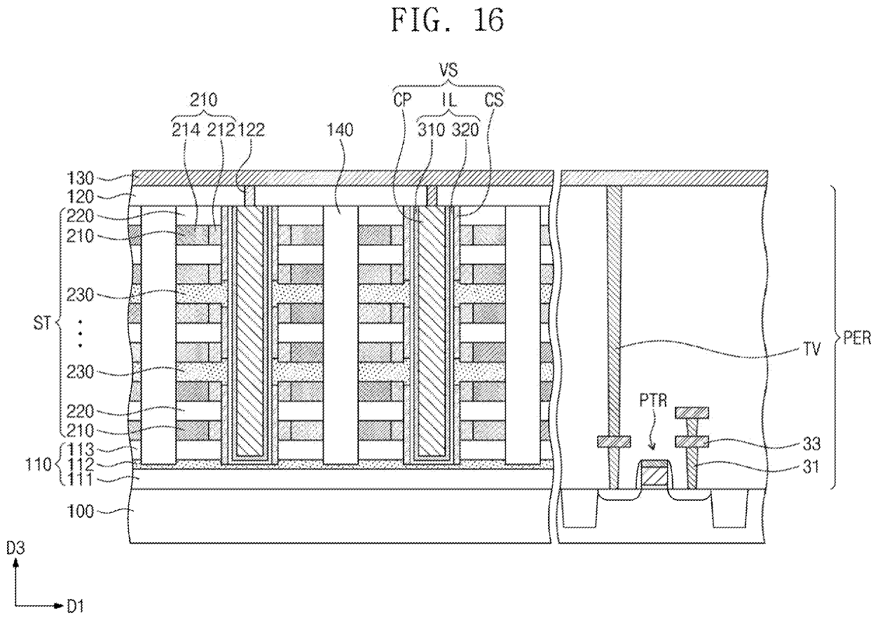

Referring to FIG. 16, the peripheral circuit layer PER may be on a peripheral region of the substrate 100. The peripheral circuit layer PER may be beside a memory cell array layer composed of the stacks ST. The peripheral circuit layer PER may be substantially the same as described with reference to FIG. 14.

The conductive line 130 may extend from the memory cell array layer to the peripheral circuit layer PER. The peripheral interconnection line 33 of the peripheral circuit layer PER may be electrically connected to the conductive line 130 through a penetration via TV.

By way of summation and review, a semiconductor memory device may have high performance and low power consumption, and next-generation nonvolatile semiconductor memory devices, such as magnetic random access memory (MRAM), phase-change random access memory (PRAM), and ferroelectric random access memory (FeRAM) devices, may be considered.

In view of a semiconductor device with high integration density and high performance, various research has been being considered to develop semiconductor devices having different properties.

According to an embodiment, a semiconductor memory device using a ferroelectric material may be provided. By using the ferroelectric material, it may be possible to realize a nonvolatile memory device that can be operated even with low power. In the semiconductor device, memory cells may be three-dimensionally arranged, and thus, the semiconductor device may have an increased integration density. According to an embodiment, it may be possible to easily form a vertical channel layer and to omit a data storing element, such as a capacitor, and this may make it possible to fabricate a highly-reliable semiconductor device through an easy fabrication process.

One or more embodiments may provide a three-dimensional semiconductor memory device with improved reliability and an increased integration density.

One or more embodiments may provide a three-dimensional semiconductor device with improved reliability and an increased integration density.

One or more embodiments may provide a method of fabricating a three-dimensional semiconductor device with improved reliability and an increased integration density.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
a stack including electrodes and a channel separation pattern, the electrodes being stacked on the substrate and spaced apart from each other, and the channel separation pattern being between some adjacent ones of the electrodes; and
a vertical structure penetrating the stack,
wherein:
the vertical structure includes a conductive pillar, a channel structure, and an interposing layer between the conductive pillar and the channel structure,
the channel structure includes a first channel layer and a second channel layer, which are vertically spaced apart from each other by the channel separation pattern,
the electrodes include first electrodes and second electrodes, which are connected to one of the first channel layer and the second channel layer,
the channel separation pattern is between the first channel layer and the second channel layer, and
the channel separation pattern is between one second electrode that is connected to the first channel layer and one first electrode that is connected to the second channel layer.

2. The semiconductor device as claimed in claim 1, wherein the interposing layer includes:
a ferroelectric layer on an outer side surface of the conductive pillar; and
a gate insulating layer between the ferroelectric layer and the channel structure.

3. The semiconductor device as claimed in claim 1, wherein:
one electrode of the first electrodes and the second electrodes is a source electrode,
another one electrode of the first electrodes and the second electrodes is a drain electrode, and
a current between the one first electrode and the one second electrode flows through a corresponding one of the first channel layer and the second channel layer that is connected to the one first electrode and the one second electrode.

4. The semiconductor device as claimed in claim 1, wherein each of the electrodes includes:
a semiconductor pattern connected to the channel structure; and
a pair of horizontal conductive patterns, which are respectively on opposite side surfaces of the semiconductor pattern.

5. The semiconductor device as claimed in claim 1, wherein the first channel layer and the second channel layer each independently include a semiconductor material, an amorphous oxide semiconductor material, or a two-dimensional material.

6. The semiconductor device as claimed in claim 1, wherein a distance between the first channel layer and the second channel layer is larger than a distance between one second electrode that is connected to the first channel layer and one first electrode that is connected to the second channel layer.

7. The semiconductor device as claimed in claim 1, wherein at least a portion of the interposing layer is between the channel separation pattern and the conductive pillar.

8. The semiconductor device as claimed in claim 1, further comprising a lower insulating layer between the stack and the substrate,
wherein a bottom surface of the channel structure is at a level between top and bottom surfaces of the lower insulating layer.

9. The semiconductor device as claimed in claim 1, wherein:
the electrodes further include third electrodes connected to one of the first channel layer and the second channel layer,
the first electrodes and the third electrodes are bit lines, respectively, and
the second electrodes are between the first electrodes and the third electrodes and are common source lines.

10. The semiconductor device as claimed in claim 1, further comprising a peripheral circuit layer between the stack and the substrate or on the stack.

11. A semiconductor device, comprising:
a substrate;
a lower insulating layer on the substrate;
a stack including electrodes stacked on the lower insulating layer and spaced apart from each other; and
a vertical structure penetrating the stack,
wherein:
the vertical structure includes a conductive pillar, a channel structure, and an interposing layer between the conductive pillar and the channel structure,
the channel structure is an outermost part of the vertical structure and is connected to the electrodes, and
a bottom surface of the channel structure is at a level between a top surface and a bottom surface of the lower insulating layer.

12. The semiconductor device as claimed in claim 11, wherein the bottom surface of the channel structure is at a level lower than a bottom surface of the conductive pillar.

13. The semiconductor device as claimed in claim 11, wherein:
the lower insulating layer includes a first lower insulating layer, a second lower insulating layer, and a third lower insulating layer, which are sequentially stacked,
the second lower insulating layer has an etch selectivity with respect to the first lower insulating layer and the third lower insulating layer, and
the bottom surface of the channel structure is at a level between a top surface and a bottom surface of the second lower insulating layer.

14. The semiconductor device as claimed in claim 11, wherein a diameter of the conductive pillar is larger than a thickness of each of the electrodes.

15. The semiconductor device as claimed in claim 11, wherein each of the electrodes includes:
a semiconductor pattern connected to the channel structure; and
a pair of horizontal conductive patterns, which are respectively on opposite side surfaces of the semiconductor pattern.

16. A semiconductor device, comprising:
a substrate;
stacks on the substrate, the stacks being spaced apart from each other in a first direction; and
a vertical structure penetrating each of the stacks,
wherein:
each of the stacks includes a first electrode and a second electrode, which is stacked on the first electrode,
the first electrode and the second electrode each extend in a second direction to be parallel to each other, and
the vertical structure includes:
a conductive pillar extending in a third direction perpendicular to the first direction and the second direction;
a channel layer connecting the first electrode and the second electrode to each other; and
a ferroelectric layer between the conductive pillar and the channel layer.

17. The semiconductor device as claimed in claim 16, wherein:
one of the first electrode and the second electrode is a bit line,
another one of the first electrode and the second electrode is a source line, and
the conductive pillar is connected to a word line.

18. The semiconductor device as claimed in claim 16, wherein the vertical structure further includes a gate insulating layer between the ferroelectric layer and the channel layer.

19. The semiconductor device as claimed in claim 16, wherein:
each of the stacks further includes a third electrode, which is stacked on the second electrode and is connected to the channel layer,
the first electrode and the third electrode are bit lines, respectively, and
the second electrode is between the first electrode and the third electrode and is a common source line.

20. The semiconductor device as claimed in claim 16, wherein the channel layer includes a semiconductor material, an amorphous oxide semiconductor material, or a two-dimensional material.
